(19) United States
(12) Patent Application Publication
(10) Pub. No.: US 2026/0359514 A1
(43) Pub. Date: Nov. 12, 2026

(54) Simulation Device and Simulation Method

(71) Applicant: Hitachi, Ltd., Chiyoda-ku, Tokyo (JP)

(72) Inventors: Wataru TORIUMI, Tokyo (JP); Takahiro HATORI, Tokyo (JP); Rui NING, Tokyo (JP)

(21) Appl. No.: 19/130,689

(22) PCT Filed: Nov. 18, 2022
(86) PCT No.: PCT/JP2022/042827

§ 371 Date: May 16, 2025

(51) Int. Cl. G06F 30/20

(52) U.S. Cl. CPC G06F 30/20

(57) ABSTRACT

Provided are a simulation device and a simulation method capable of coping with a bottleneck and obtaining an acceptable human flow simulation result. The simulation device that simulates a human flow includes: a storage unit; and a control unit for simulation, in which the storage unit stores layout information and a human model that holds at least destination information indicating a destination in the layout information, and current position information, and in a case where a bottleneck at which a flow rate of the human models is limited is detected within a certain range ahead in a movement direction of the human model, the control unit changes movement control for the human model from movement control in a case where no bottleneck is detected.

### TECHNICAL FIELD

The present invention relates to a simulation device and a simulation method for simulating a human flow.

### BACKGROUND ART

In recent years, a human flow simulation system capable of reproducing a flow of pedestrians on a computer for the purpose of evaluating countermeasures against problems caused by local concentration of a crowd, such as prior evaluation of an evacuation guidance plan at the time of events or disasters or prior evaluation of a congestion situation accompanying construction of new commercial facilities has attracted attention.

In relation to the human flow simulation system, for example, PTL 1 proposes “obtaining a ratio of the number of moving agents proceeding in one direction and the number of moving agents proceeding in the other direction at a selected edge for each direction, calculating a width size relative to a direction in which the moving agent proceeds from the ratio with respect to a width of the edge, calculating, with respect to each of the moving agents, a population density based on an area of a section which is obtained from a length of a forward region from a position of the moving agent and the width size calculated for the direction in which the agent proceeds, and the moving agent existing in the section for each direction, and calculating, for each moving agent, a movement speed of the moving agent based on a free walking speed of agent information, the calculated population density, and a predetermined parameter” for the purpose of accurately simulating movement by simulating an interaction caused by a difference in proceeding direction.

### CITATION LIST

### Patent Literature

PTL 1: WO 2021/044481 A

### SUMMARY OF INVENTION

### Technical Problem

According to PTL 1, the walking speed is determined based on the number of moving people and the number of people moving in an opposite direction in the edge, but there is no mention of determination of a movement direction for avoiding a contact in a crowded situation. Therefore, for example, in an environment where an obstacle or a narrow portion, which becomes a bottleneck, exists, a complete deadlock sometimes occurs when an opposing flow to the bottleneck occurs.

In view of the above, an object of the present invention is to provide a simulation device and a simulation method capable of coping with a bottleneck and obtaining an acceptable human flow simulation result.

### Solution to Problem

In view of the above, in the present invention, “a simulation device that simulates a human flow includes: a storage unit; and a control unit for simulation, in which the storage unit stores layout information and a human model that holds at least destination information indicating a destination in the layout information, and current position information, and in a case where a bottleneck at which a flow rate of the human models is limited is detected within a certain range ahead in a movement direction of the human model, the control unit changes movement control for the human model from movement control in a case where no bottleneck is detected”.

Further, in the present invention, “a simulation method for simulating a human flow includes: a storage method; and a control method for simulation, in which in the storage method, an arbitrary layout and a human model that holds at least destination information indicating a destination in the layout, and current position information are stored, and in the control method, in a case where a bottleneck region in which a passage width is small is detected in a range of a field of view of the human model, an effect of avoiding an opposing person is enhanced more than usual”.

### Advantageous Effects of Invention

It is possible to provide a simulation device and a simulation method capable of coping with a bottleneck and obtaining an acceptable human flow simulation result.

### BRIEF DESCRIPTION OF DRAWINGS

FIG. 1 is a diagram illustrating a configuration example of a simulation device according to an embodiment of the present invention.

FIG. 2 is a diagram illustrating the inside of a building as an example of an environment for which simulation is to be performed.

FIG. 3 is a diagram illustrating that a passage fragment is set inside the building of FIG. 2.

FIG. 4a is a diagram illustrating a concept of determining a movement direction of a human model in a normal state.

FIG. 4b is a diagram illustrating a state in which an opposing person M2 is detected ahead in the movement direction.

FIG. 4c is a diagram illustrating a state in which the opposing person M2 is detected in the movement direction at a bottleneck portion.

FIG. 5 is a diagram illustrating Method 1 for bottleneck recognition.

FIG. 6 is a diagram illustrating Method 2 for bottleneck recognition.

FIG. 7 is a diagram illustrating a processing flow in a prior preparation stage.

FIG. 8 is a diagram illustrating a processing flow during simulation.

### DESCRIPTION OF EMBODIMENTS

Hereinafter, embodiments of the present invention will be described with reference to the drawings.

### First Embodiment

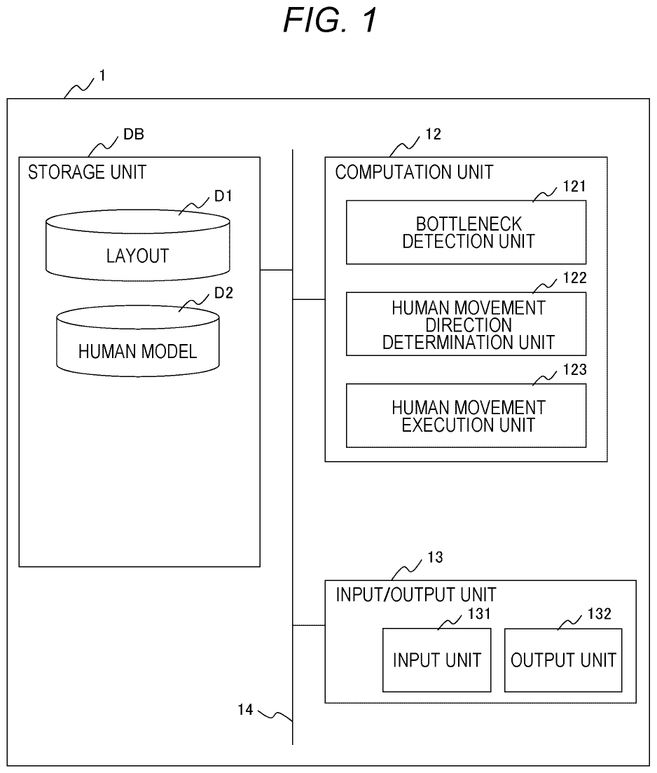

FIG. 1 is a diagram illustrating a configuration example of a simulation device according to a first embodiment of the present invention. A simulation device 1 has a configuration in which a storage unit DB, a computation unit 12, and an input/output device 13 are connected to a bus 14.

Among them, the storage unit DB stores layout information D1 of an environment for which simulation is to be performed and a human model D2 that performs movement behavior under the environment. A functional processing content of the computation unit 12 can be said to include respective processing units including a bottleneck detection unit 121, a human movement direction determination unit 122, and a human movement execution unit 123. The input/output device 13 includes an input unit 131 that performs appropriate setting of a simulation condition or the like, and an output unit (display unit) 132 that outputs input setting data and a simulation result.

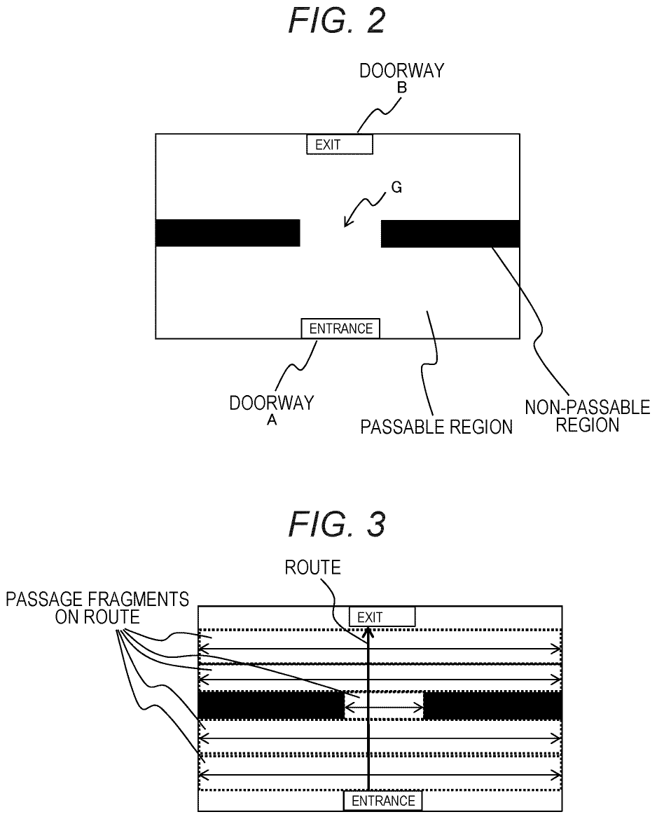

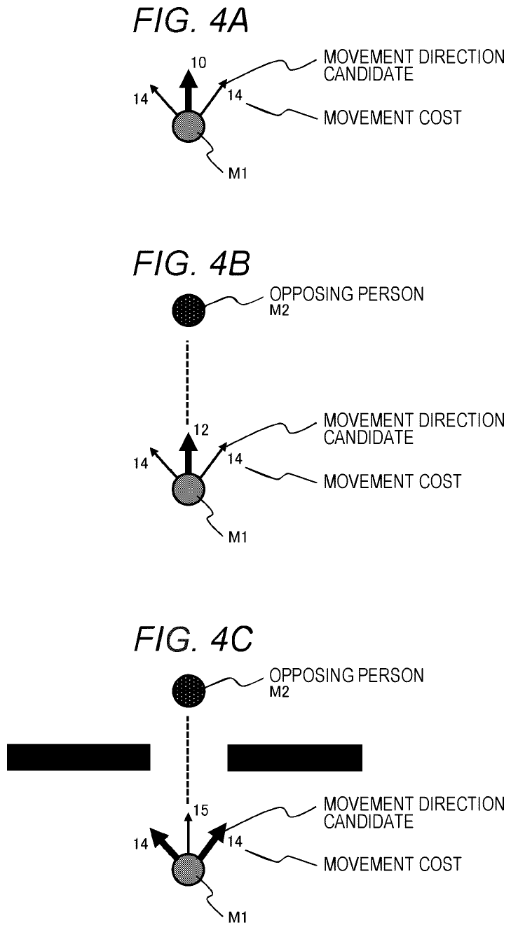

Hereinafter, an operation of the simulation device of FIG. 1 will be described in detail, and several items will be described as a premise. First, as for the environment for which simulation is to be performed, an appropriate place or facility can be selected according to each analysis purpose, and in the embodiment, the inside of a building as illustrated in FIG. 2 is taken as an example. As a method of estimating a movement direction of a person on a simulation model, it is assumed that the estimation is performed using a cost method in FIGS. 4a, 4b, and 4c.

The building illustrated in plan view of FIG. 2 as an example of the environment for which simulation is to be performed includes a plurality of doorways A and B. The doorway A faces, for example, an external passage or the like, and the doorway B is at a position where an elevator for moving to each floor in the building is installed. Although illustrated in a simplified manner here, a Staircase and the like are additionally included as the doorways, and a plurality of doorways may be included. Since a security gate G or the like is installed between the doorways A and B in the building of FIG. 2, a region in plan view is divided into a passable region and a non-passable region.

In order to perform human flow simulation for FIG. 2, for example, it is necessary to set conditions necessary for modeling movement of a person in the building in advance. A setting procedure roughly includes three steps. First, building layout setting in which a layout, a floor dimension, and a height of each floor in the building are set is performed with reference to an architectural drawing or the like. Next, various in-building facilities such as elevators, escalators, security gates, and automatic doors are arranged, and building facility setting in which a specification of each facility is set is performed. Then, an entrance and a doorway of a room are set, and human movement setting in which the number of people moving from one location to another location is set is performed. These steps of setting processing are performed in advance while performing appropriate display using the input/output device 13.

When the building layout setting and the building facility setting are completed, the layout information Dl is formed as illustrated in FIG. 2 in the storage unit of FIG. 1, and more specifically, the layout information D1 is formed and stored as illustrated in FIG. 3 in the present invention. In FIG. 2, the layout, the floor dimension, and the height of each floor in the building are set, but in FIG. 3, a space between the doorways A and B is further divided into a plurality of regions in a direction of human movement, and the layout information D1 includes a distance in an orthogonal direction. The distance is obtained by setting a plurality of passage fragments on a route of human movement (for example, the shortest distance between the doorways A and B) and determining a distance in a lateral direction for each passage fragment.

Furthermore, in the human movement setting on the premise of the above setting, the entrance and the doorway of the room are set, and the number of people moving from one location to another location is set. Information regarding the entrance and the doorway of the room is included in the layout information D1 and managed.

Here, as for handling of the human model at this time, in particular, the cost method is adopted in the present invention as a concept of determining a movement direction of the human model. FIG. 4a is a diagram illustrating the concept of determining the movement direction of the human model in a normal state. Here, for example, eight directions (a front direction, a rear direction, a left direction, and a right direction, and a left-front direction, a right-front direction, a left-rear direction, and a right-rear direction) are set on a floor plane as the movement direction of the human model M1, and a cost is set for each direction. The cost is set in terms of magnitude. Normally, in a case where 10 is set for the front direction, a numerical value larger than 10 is set for other directions. In FIG. 4a, only the front direction, the left-front direction, and the right-front direction are simply described, and 14, which is larger than 10, is set for the left-front direction and the right-front direction. In this setting, a direction for which the cost is lowest is set as a proceeding direction.

In addition, in actual simulation on the premise of such cost setting, when an opposing person M2 is detected ahead in the movement direction as illustrated in FIG. 4b, a cost for a detection direction is adjusted to be higher than an initial setting value of 10, for example, 12. Although the cost after the adjustment is 12, it is possible to set the movement direction of the human model so as to take an avoidance action in the left-front direction, the right-front direction, or the like according to the principle of setting the direction for which the cost is lowest as the proceeding direction when the cost becomes larger than the cost for the left-front direction and the right-front direction, by setting the cost to be higher as a distance from the opposing person M2 decreases.

In a human model storage unit DB2 of FIG. 1, information regarding the human model M1 in which the human movement setting is performed is stored for each person. These pieces of information are the number of people in time series, entry and exit routes of each person, destinations, cost information for each direction, or include a walking speed or the like.

After preparing the contents to be stored as described above, the bottleneck detection unit 121 in the computation unit 12 detects a bottleneck on a route to a destination. The bottleneck is, for example, a place or a position where congestion and a jam are likely to occur in an environment where an obstacle exists or a narrow portion exists, which causes an opposing flow, and a place where such a tendency is likely to be exhibited is set as a bottleneck environment.

In the simulation, the human model M1 is assumed to proceed along a route (here, it is assumed that a straight and shortest distance route is adopted) from the current position (for example, the doorway A of the building) toward the doorway B as the destination, and the presence or absence of the bottleneck on the route is set in advance.

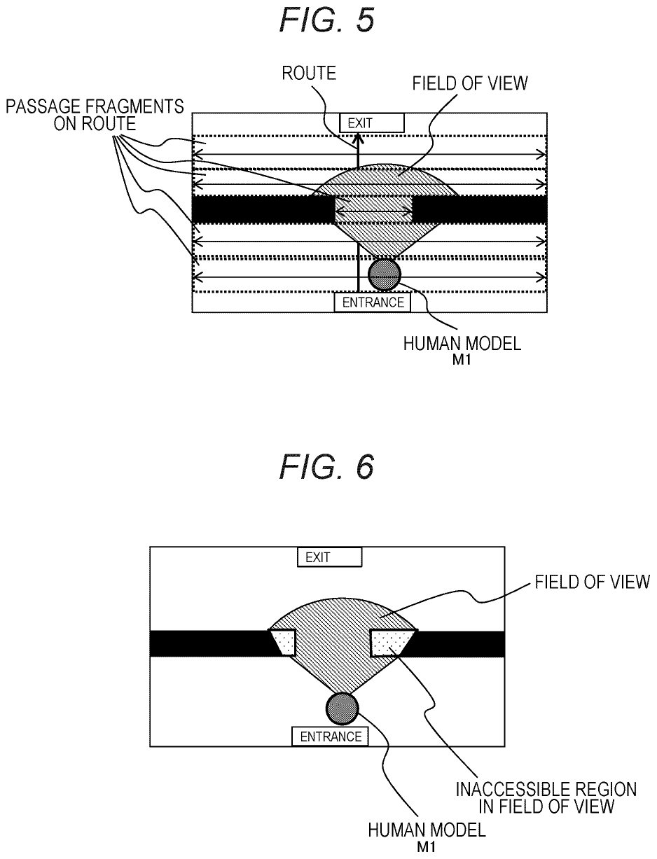

In FIG. 5, Method 1 for bottleneck recognition is obtained in consideration of the distance in the lateral direction set for each passage fragment of FIG. 3 stored in the layout information D1. In FIG. 3, all passage widths on the route from an entrance to an exit are identified in advance before the simulation, and in the simulation, the bottleneck is detected using the smallest passage width among the passage widths included in a field of view of the human model M1 at the time of determining the movement direction.

Method 2 for bottleneck recognition is a method that does not use prior preparation information (distance information for each passage fragment) in FIG. 3. Here, as illustrated in FIG. 6, when determining a movement direction of a person during the simulation, in a case where a region to which the person is not accessible has a certain area or more in a certain forward range (the field of view), it is determined that there is a bottleneck.

In this manner, the bottleneck detection unit 121 in the computation unit 12 detects the bottleneck in prior preparation stage before the simulation is performed, or detects the bottleneck during the simulation.

In any case, in a situation where the bottleneck is detected, the human movement direction determination unit 122 in FIG. 1 determines the direction of the human movement in the simulation by cost setting processing. A cost operation when the opposing person is detected in the movement direction described with reference to FIG. 4b is also processing in the human movement direction determination unit 122.

In the present invention, it is further assumed that the opposing person M2 is detected in the movement direction at the bottleneck portion. The human movement direction determination unit 122 detects occurrence of such a situation in the simulation and performs the cost operation as illustrated in FIG. 4c. As a result, a lane forming effect (a parameter for avoiding the opposing person) is enhanced when the bottleneck is detected in the proceeding direction of the person. Specifically, in a case where the bottleneck is detected, the next movement direction is easily determined by applying a larger cost than usual to a direction in which the opposing person M2 is present.

In a case where the cost for the front direction at the time of detection of the opposing person in FIG. 4b is increased from 10 for the normal state to 12, the cost for the front direction is increased to 15 at once under the condition of FIG. 4c, which exceeds 14 of the cost for the other directions, so that the avoidance action is immediately taken. In addition, the lane forming effect can be caused in the entire environment by performing the same cost operation for other human models.

It is preferable to consider the following points for the above cost operation. For example, an avoidance direction is determined in accordance with the rule of right-side walking in Japan, so that the lane formation effect is likely to occur for the whole environment. In addition, it is preferable to set a larger cost as the bottleneck is narrower. Furthermore, in FIG. 6, it is preferable to also handle, as an inaccessible region, a region where the opposing person M2 is present at the bottleneck portion in the field of view. The cost applied for the direction in which the opposing person M2 is present when determining the movement direction is preferably inversely proportional to a size of the inaccessible region in the field of view.

According to the cost operation described above, it is possible to make a motion preventing a deadlock at the bottleneck without changing human flow characteristics at other points. This leads to an improvement in accuracy of a simulator and satisfaction for the motion.

In the description of the premise of the above cost setting, the cost for the front direction is set to be lower than the cost for other directions, a cost increase operation is performed according to the presence of the opposing person or the bottleneck, and a direction for which the cost is low is set as the proceeding direction. However, a magnitude relationship thereof and the like may be reversed. That is, the same applies even in a case where the cost for the front direction is set to be higher than the cost for other directions, a cost decrease operation is performed according to the presence of the opposing person or the bottleneck, and a direction for which the cost is high is set as the proceeding direction.

As described above, in the present invention, when the bottleneck is detected ahead of the movement direction of the person during moving processing of the person, an effect of avoiding the opposing person is enhanced more than usual. In addition, by increasing the cost for a position where the opposing person is present and a position in front of the opposing person in inverse proportion to the width of the bottleneck, the effect of avoiding the opposing person is enhanced. For this purpose, all the passage widths on the route are identified in advance before the simulation, and the bottleneck is preferably detected using the width of the passage included in the field of view of the person during the simulation. In addition, it is preferable to enhance the effect of avoiding the opposing person by increasing the cost for the position where the opposing person is present and the position in front of the opposing person in inverse proportion to an area of the non-passable region in the field of view of the person.

### Second Embodiment

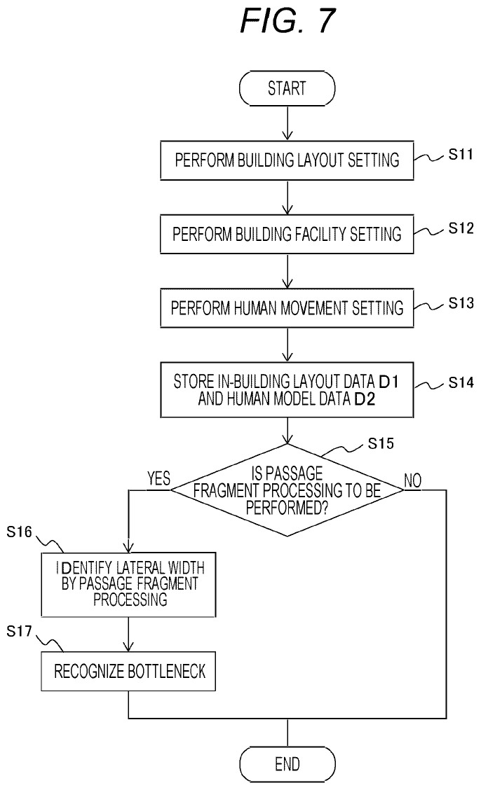

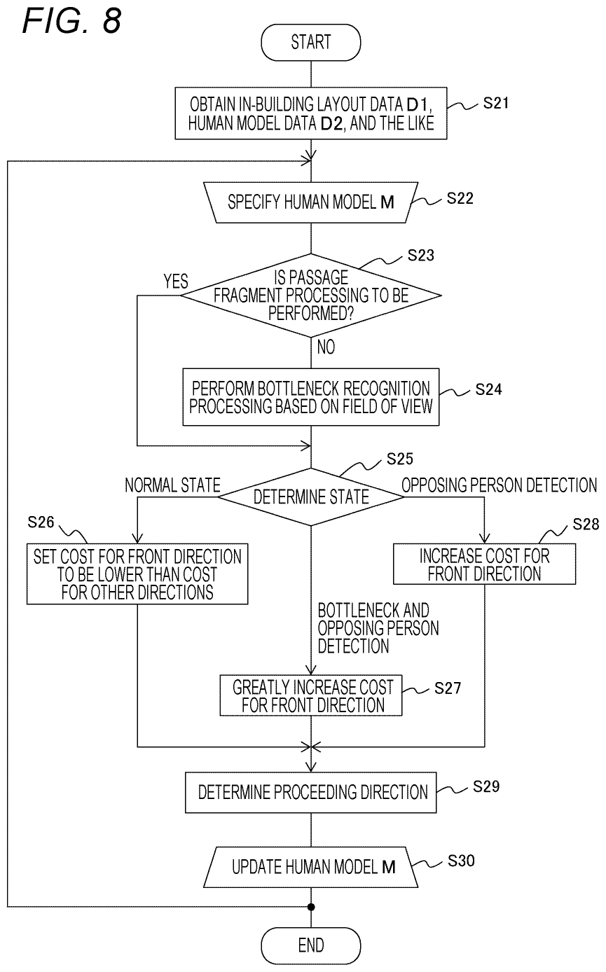

In second embodiment, a simulation method will be described. FIG. 7 illustrates a processing flow in a prior preparation stage, and FIG. 8 illustrates a processing flow during simulation.

Building layout setting is performed in the first processing step S11 in FIG. 7, building facility setting is performed in processing step S12, and person movement setting is performed in processing step S13, and by execution of a series of these steps of processing, layout information D1 and a human model D2 are formed and stored in a storage unit in processing step S14.

In processing step S15, it is determined whether or not to perform passage fragment processing. In the case of performing the passage fragment processing, the passage fragment processing is performed in processing step S16 to identify a lateral width. Subsequently, in processing step S17, it is recognized that the position is the bottleneck according to the identified width, and the position is stored in a state of being included in the layout information D1.

In the following processing flows of FIGS. 7 and 8, two sets of bottleneck detection methods are adopted. Therefore, when only one of the bottleneck detection methods is adopted, it is sufficient if the determination processing of determining whether or not to perform the passage fragment processing in processing steps S15 and S23 is deleted as appropriate.

In FIG. 8, which illustrates the processing during the simulation, first, in processing step S21, the layout information D1, the human model D2, and the like of an environment in which human flow processing is performed are obtained. In processing step S22, repetitive processing is performed while changing a human model M1 and a processing time until processing step S30. It is assumed that the environment and thus a layout are specified.

In the repetitive processing, in processing step S23, it is determined whether or not the passing fragment processing has been performed. In a case where the passage fragment processing has not been performed, bottleneck recognition processing based on the field of view is performed in processing step S24. In a case where the passage fragment processing has been performed, after execution of processing step S24, the processing proceeds to processing of processing step S25.

In the processing of processing step S25, the current state is determined according to the presence of the opposing person M2 for the selected human model M1 and a bottleneck confirmation state. As a result, classification into three modes including the normal state (no bottleneck and no opposing person), an opposing person detection state, and an opposing person detection and bottleneck state is made.

In the normal state, the cost for the forward direction is set to be lower than the cost for the other directions in processing step S26, the cost for the forward direction is increased in processing step S28 when the presence of the opposing person M2 ahead in the movement direction is detected, and the cost for the forward direction is greatly increased in processing step S27 when in the opposing person detection and bottleneck state.

After cost operation processing is performed, the processing proceeds to processing step S29, and the proceeding direction is determined according to the cost, and movement of the human model in the determined proceeding direction is performed. This processing is processing in a human movement execution unit 123 in FIG. 1. Processing step S30 is termination determination processing for iteration, and the above processing is repeated for the human models corresponding to the set number of people over a simulation period while changing a time. This repetitive processing is also performed on a time axis, thereby simulating a human flow in time series.

According to the first embodiment and the second embodiment, it is possible to provide a simulation device and a simulation method capable of coping with a bottleneck and obtaining an acceptable human flow simulation result.

### REFERENCE SIGNS LIST

1 simulation device
DB storage unit
12 computation unit
13 input/output device
14 bus
D1 layout information
D2 human model
121 bottleneck detection unit
122 human movement direction determination unit
123 human movement execution unit
131 input unit
132 output unit (display unit)

1. A simulation device that simulates a human flow, the simulation device comprising:
a storage unit; and
a control unit for simulation,
wherein the storage unit stores layout information and a human model that holds at least destination information indicating a destination in the layout information, and current position information, and
in a case where a bottleneck at which a flow rate of the human models is limited is detected within a certain range ahead in a movement direction of the human model, the control unit changes movement control for the human model from movement control in a case where no bottleneck is detected.

2. The simulation device according to claim 1, wherein
the control unit includes a bottleneck detection unit that detects the bottleneck, a human movement direction determination unit that sets a cost for a plurality of directions around the human model and determines the movement direction according to a magnitude of the cost, and a human movement execution unit that moves the human model in the simulation, and
the human movement direction determination unit changes the cost for a front direction of the human model to a first value when the human model detects an opposing person on a route from a current position to a destination position, and changes the cost for the front direction of the human model to a second value when the bottleneck is detected and the opposing person is detected on the route.

3. The simulation device according to claim 2, wherein the bottleneck detection unit stores position information of the detected bottleneck in the storage unit, and the human movement direction determination unit refers to the position information of the bottleneck stored in the storage unit.

4. The simulation device according to claim 2, wherein when determining the movement direction of the human model during the simulation, the bottleneck detection unit detects, as the bottleneck, a region to which the human model is not accessible in a certain forward range in a case where the region has a certain area or more.

5. The simulation device according to claim 2, wherein the second value varies according to a passage width of the human model when the passage width is decreased by the bottleneck.

6. A simulation method for simulating a human flow, the simulation method comprising:
a storage method; and
a control method for simulation,
wherein in the storage method, an arbitrary layout and a human model that holds at least destination information indicating a destination in the layout, and current position information are stored, and
in the control method, in a case where a bottleneck region in which a passage width is small is detected in a range of a field of view of the human model, an effect of avoiding an opposing person is enhanced more than usual.
